(19) United States
(12) Patent Application Publication
(10) Pub. No.: US 2014/0083481 A1
(43) Pub. Date: Mar. 27, 2014

(54) PHOTOVOLTAIC MODULE

(71) Applicant: 3M INNOVATIVE PROPERTIES COMPANY, St. Paul, MN (US)

(72) Inventors: Timothy J. Hebrink, Scandia, MN (US); Daniel T. Chen, St. Paul, MN (US)

(73) Assignee: 3M INNOVATIVE PROPERTIES COMPANY, St. Paul, MN (US)

(21) Appl. No.: 14/116,663

(22) PCT Filed: May 9, 2012
(86) PCT No.: PCT/US2012/037045

§ 371 Date: Nov. 8, 2013

Related U.S. Application Data
(60) Provisional application No. 61/484,096, filed on May 9, 2011.

(51) Int. Cl. H01L 31/052

(52) U.S. Cl. CPC H01L 31/0527
USPC 136/246

(57) ABSTRACT

A photovoltaic module including a backsheet and a plurality of photovoltaic cells overlying the backsheet is disclosed. The backsheet has open areas not covered by the photovoltaic cells. The backsheet may be a reflective backsheet that includes a multilayer optical film, or the photovoltaic module may include a reflective multilayer optical film separate from the backsheet. The multilayer optical film has an optical stack with a plurality of alternating first and second optical layers having different indices of refraction and a left band edge in a range from 600 nanometers to 900 nanometers. The multilayer optical film reflects at least a portion of light in a range of wavelengths that corresponds with the absorption bandwidth of the photovoltaic cell.

### CROSS REFERENCE TO RELATED APPLICATION

This application claims priority to U.S. Provisional Application No. 61/484,096, filed May 9, 2011, the disclosure of which is incorporated by reference in its entirety herein.

### BACKGROUND

Many conventional photovoltaic modules are laminated structures including a front sheet and a back sheet that may be made from the same or different materials. Positioned between the front and back sheets are typically interconnected photovoltaic cells and an encapsulant that surrounds the photovoltaic cells and holds the laminated structure together. The back sheet may provide at least one of the following functions for the photovoltaic module: physical protection, for example, against puncture and abrasion resistance, moisture protection, electrical insulation, and weatherability. Back sheets are typically black or white, with white back sheets providing diffuse reflection onto photovoltaic cells by scattering incident light. Back sheets have also been provided with V-shaped grooves or other light-reflecting facets that can provide increased light to a photovoltaic cell through total internal reflection; see, e.g., U.S. Pat. No. 4,235,643 (Amick); U.S. Pat. No. 5,994,641 (Kardauskas); and U.S. Pat. No. 6,660,930 (Gonsiorawski).

Electromagnetic radiation of certain wavelengths reflected onto a photovoltaic cell may adversely affect the photovoltaic cell. For example, certain wavelengths in the infrared spectrum can cause certain photovoltaic cells to undesirably increase in temperature. As a result, the photovoltaic cells may lose efficiency and degrade over time due the excessive thermal exposure. Long term exposure to ultraviolet (UV) light also typically leads to premature degradation of components of the photovoltaic cell. Some solar concentrating mirrors, useful in some photovoltaic applications, that reflect wavelengths corresponding to the absorption bandwidth of a selected solar cell and either transmits or absorbs a major portion of light outside this bandwidth have been disclosed in Int. Pat. App. Pub. No. WO 2009/140493 (Hebrink et al.).

### SUMMARY

A photovoltaic module including a backsheet and a plurality of photovoltaic cells overlying the backsheet is disclosed. The backsheet has open areas not covered by the photovoltaic cells. The backsheet may be a reflective backsheet that includes a multilayer optical film, or the photovoltaic module may include a reflective multilayer optical film separate from the backsheet. The multilayer optical film has a left band edge in a range from 600 nanometers to 900 nanometers.

In one aspect, the present disclosure provides a photovoltaic module including a reflective backsheet and a plurality of photovoltaic cells overlying the reflective backsheet. The plurality of photovoltaic cells are spaced apart from each other such that open areas of the reflective backsheet are not covered by the plurality of photovoltaic cells. The reflective backsheet includes a multilayer optical film having an optical stack comprising a plurality of alternating first and second optical layers with different indices of refraction and having a left band edge in a range from 600 nanometers to 900 nanometers. The photovoltaic cells have an absorption bandwidth, and the multilayer optical film reflects at least a portion of light in a range of wavelengths that corresponds with the absorption bandwidth of the photovoltaic cell.

In another aspect, the present disclosure provides a photovoltaic module including backsheet and a plurality of photovoltaic cells overlying the backsheet. The plurality of photovoltaic cells are spaced apart from each other such that open areas of the backsheet are not covered by the plurality of photovoltaic cells. The photovoltaic module further includes a reflective film positioned over the backsheet in at least some of the open areas of the backsheet. The reflective film includes a multilayer optical film having an optical stack comprising a plurality of alternating first and second optical layers with different indices of refraction and having a left band edge in a range from 600 nanometers to 900 nanometers. The photovoltaic cells have an absorption bandwidth, and the multilayer optical film reflects at least a portion of light in a range of wavelengths that corresponds with the absorption bandwidth of the photovoltaic cell.

Depending on aesthetic requirements, the reflective backsheet or reflective film may appear colorless or colored. In some embodiments, the multilayer optical film is a color-shifting film, and the reflective backsheet or reflective film may appear to have a different color when viewed at a zero-degree viewing angle than when it is viewed off-angle. Such color-shifting may be aesthetically pleasing and may provide a unique appearance when the photovoltaic module is installed on a building or incorporated into a building The reflective backsheet or reflective film may provide a useful alternative to white backsheets, which are disfavored in some applications because they are considered to detract from the aesthetic appeal of a building where they are used.

Because the multilayer optical film useful for making the reflective backsheet or reflective film disclosed herein has a left band edge in a range from 600 to 900 nanometers, the photovoltaic module according to the present disclosure may have reduced glare in comparison to conventional backsheets such as black or white backsheets not provided with the multilayer optical film described herein.

Furthermore, because the multilayer optical film useful for making the reflective backsheet or reflective film disclosed herein has a left band edge in a range from 600 to 900 nanometers, in some embodiments, the photovoltaic module according to the present disclosure may be at least partially transmissive to visible light. In these embodiments, typically any substrate to which the multilayer optical film is applied and any coatings provided on the multilayer optical film or the photovoltaic module are also at least partially transmissive to visible light. Advantageously, when the photovoltaic module of these embodiments is installed in a building or structure, the module allows visible light to enter into the building or structure (that is, it allows daylighting).

In some embodiments, because the multilayer optical film reflects at least a portion of light in a range of wavelengths that corresponds with the absorption bandwidth of the photovoltaic cell, the power output of the photovoltaic cell may be increased. In some of these embodiments, the multilayer optical film is provided with a textured surface. The textured surface may increase the light provided to the photovoltaic cell through total internal reflection.

In this application:

Terms such as “a”, “an” and “the” are not intended to refer to only a singular entity, but include the general class of which a specific example may be used for illustration. The terms “a”, “an”, and “the” are used interchangeably with the term “at least one”.

The phrase “at least one of” followed by a list of two or more items refers to any one of the items in the list and any combination of two or more items in the list.

The term “light” refers to electromagnetic radiation, whether visible to the unaided human eye or not.

The term “polymer” refers to a macromolecular compound consisting essentially of one or more repeated monomeric units, or a mixture of macromolecular compounds that consist essentially of one or more like repeated monomeric units.

The term “plurality” means more than one. The number of photovoltaic cells in the photovoltaic module according to the present disclosure is at least two, but the number of photovoltaic cells in the module can be modified depending on the desired size of the photovoltaic module and the photovoltaic cells.

All numerical ranges are inclusive of their endpoints and non-integral values between the endpoints unless otherwise stated.

### BRIEF DESCRIPTION OF DRAWINGS

The disclosure may be more completely understood in consideration of the following detailed description of various embodiments of the disclosure in connection with the accompanying drawings, in which:

FIG. 1 is a plan view of a photovoltaic module according to some embodiments of the present disclosure, with part of an optional cover broken away;

FIG. 2 is a fragmentary cross-sectional view of a portion of the photovoltaic module of FIG. 1;

FIG. 3 is a cross-sectional view of a photovoltaic module according to other embodiments of the present disclosure; and

FIG. 4 is a schematic cross-sectional view of a reflective backsheet in a photovoltaic module according to yet other embodiments of the present disclosure.

### DETAILED DESCRIPTION

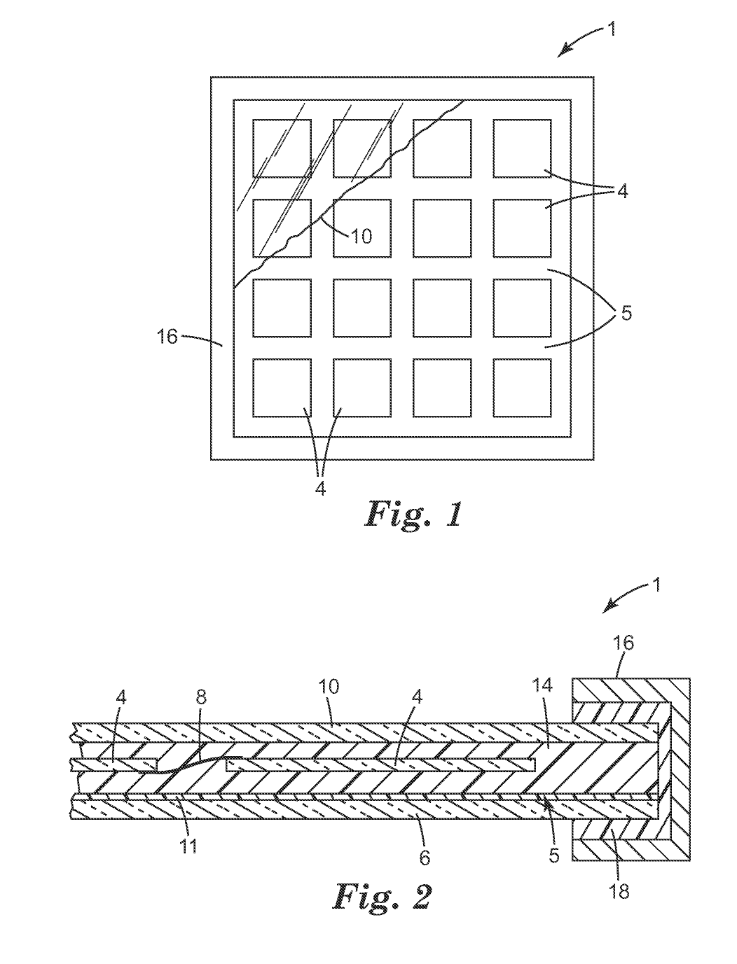

FIGS. 1 and 2 illustrate a photovoltaic module 1 according to some embodiments of the present disclosure. Photovoltaic module 1 includes a plurality of rectangular photovoltaic cells 4, although the shape, size, and number of photovoltaic cells may be different from the illustrated example. Although not shown, each photovoltaic cell typically comprises a front contact on its front surface in the form of a grid comprising an array of narrow, elongate parallel fingers interconnected by one or more bus bars, and a rear contact on its rear surface. Photovoltaic cells may be made, for example, as illustrated and described U.S. Pat. No. 4,751,191 (Gonsiorawski et al.), U.S. Pat. No. 5,074,920 (Gonsiorawski et al.), U.S. Pat. No. 5,118,362 (St. Angelo et al.), U.S. Pat. No. 5,178,685 (Borenstein et al.), U.S. Pat. No. 5,320,684 (Amick et al.), and U.S. Pat. No. 5,478,402 (Hanoka). The photovoltaic cells are typically arranged in parallel rows and columns although other configurations may be useful. Referring to FIG. 2, photovoltaic cells are typically interconnected by electrical leads 8 which usually are in the form of flat copper ribbons. The usual practice in making a photovoltaic module is to interconnect the cells in each row in series so as to form strings, and then connect the strings in series or in parallel, or in some series/parallel combination, according to the voltage and current requirements of electrical system into which the module is to be installed. In FIG. 2, adjacent cells in a string are connected in series by soldering one end of a flexible copper ribbon 8 to the back electrode of one photovoltaic cell and soldering the opposite end of the same ribbon to a bus bar of the front contact on the next succeeding photovoltaic cell.

In the embodiment illustrated in FIG. 2, the photovoltaic module includes a reflective backsheet. In the illustrated embodiment, the backsheet includes a substrate 6 that may be made of various materials and may be stiff or flexible. The substrate 6 is typically an electrically insulating material such as glass, a plastic, a plastic reinforced with glass fibers, or a wood particle board. In some embodiments, the substrate is a fluoropolymer film available, for example, from E.I DuPont du Nemours & Co., Wilmington, Del., under the trade designation “TEDLAR”. The reflective backsheet is typically made reflective by the multilayer optical film 11 positioned on the substrate 6. The multilayer optical film 11 is described in detail below. An optional tie layer, such as any of those described below, may be employed in bonding the multilayer optical film to the substrate 6. In some embodiments, the substrate 6 need not be present. In these embodiments, the multilayer optical film forms the reflective backsheet. The reflective backsheet has open areas 5 that are not covered by the plurality of photovoltaic cells, which is shown best in FIG. 1.

Overlying the cells in some embodiments as shown in FIGS. 1 and 2 is an optional front cover 10. The front cover 10 is typically a planar light-transmitting and electrically non-conducting cover in sheet form that also functions as part of the cell support structure. Cover member 10 may have a thickness in the range of about ⅛″ to about ⅜″, in some embodiments, at least about ¼″, and has an index of refraction between about 1.3 and 3.0. Exemplary useful materials for front cover 10 include glass or plastic (e.g., a polycarbonate or an acrylic polymer).

Interposed between substrate 6 and transparent front cover 10 and surrounding the cells 4 and their electrical connector ribbons 8 is an encapsulant 14 which is typically made of suitable light-transparent, electrically non-conducting material. An exemplary useful encapsulant 14 is the ethylene vinyl acetate copolymer known in the trade as “EVA”, or an ionomer. Typically, an encapsulant 14 is provided in the form of discrete sheets that are positioned below and on top of the plurality of photovoltaic cells, with those components in turn being sandwiched between the multilayer optical film 11 and the front cover 10. Subsequently that sandwich is typically heated under vacuum, causing the encapsulant sheets to become liquified enough to flow around and encapsulate the cells and simultaneously fill any voids in the space between the front cover and the back sheet that may result from evacuation of air. Upon cooling, the liquified encapsulant solidifies and is cured in situ to form a transparent solid matrix that envelops the cells and fully fills the space between the multilayer optical film 11 and cover 10 that is not occupied by the mutually spaced cells and the components that form their electrical interconnections. The encapsulant adheres to the front and back sheets so as to form a laminated subassembly.

Regardless of how the laminated subassembly is made, it typically is provided with and secured to a surrounding frame 16, with a sealant 18 usually disposed between the frame and the edges of the laminated subassembly. The frame may be made of metal or molded of a suitable material such as an organic plastic or elastomer material. Although not shown, it is to be understood that a photovoltaic module such as shown in FIGS. 1 and 2 also can be provided with electrical terminals for connecting the module to another module or directly into an electrical circuit, with the terminals usually being affixed to the backsheet substrate 6. Additionally, the photovoltaic module or a portion thereof may be reinforced, for example, by injection cladding, corrugation, or addition of ribs, foam spacer layers, or honeycomb structures to improve its dimensional stability.

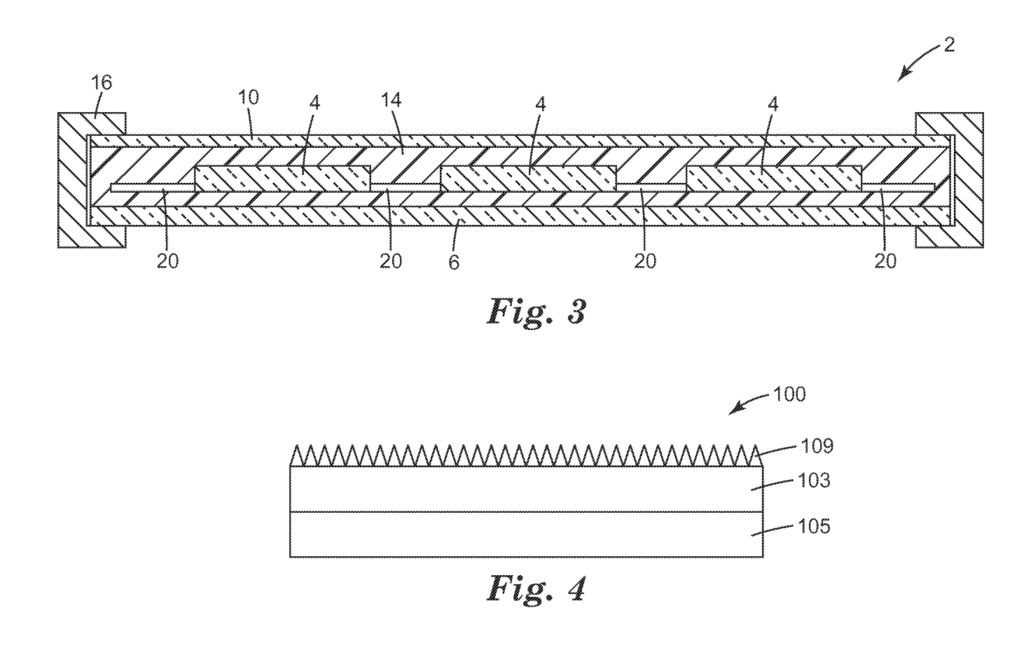

FIG. 3 illustrates another embodiment of the photovoltaic module according to the present disclosure. Photovoltaic module 2 includes a backsheet substrate 6, which may be made from any of the substrates described above for the embodiments illustrated in FIGS. 1 and 2. A plurality of photovoltaic cells 4 overly the backsheet substrate 6. The photovoltaic cells are spaced apart from each other such that open areas of the backsheet are not covered by the plurality of photovoltaic cells 4. In at least some of these open areas is positioned reflective film 20. The reflective film 20 is made at least partially of the multilayer optical film described in detail below. The reflective film 20 may be provided as discrete film portions as in the illustrated embodiment. The film portions may be provided as strips between rows or columns of photovoltaic cells 4. In other embodiments (not shown), the reflective film may be provided as a continuous layer that underlies the photovoltaic cells 4 but is separate from the backsheet substrate 6. The photovoltaic module 2 may be constructed by providing an encapsulant 14 in the form of a discrete sheet, for example, positioned between the backsheet substrate 6 and the reflective film or film portions 20 and another discrete sheet of encapsulant 14 positioned on top of the plurality of photovoltaic cells 4, with the reflective film 20 and the photovoltaic cells 4 being sandwiched between the backsheet substrate 6 and the front cover 10. Curing the encapsulant 14 may be carried out, for example, as described above.

In any of the embodiments of the photovoltaic modules disclosed herein, including the illustrated embodiments, the photovoltaic module may have a range of open areas. For example, the percentage of area of the backsheet or reflective backsheet that may be open can be at least 5, 8, 10, 15, or 20 percent. In some embodiments, the area of the backsheet or reflective backsheet that may be open can be up to 25, 30, 40, or 50 percent.

Photovoltaic modules according to the present disclosure include a reflective backsheet or a reflective film positioned over a backsheet. The reflective backsheet or reflective film includes a multilayer optical film having an optical stack with a plurality of alternating first and second optical layers with different indices of refraction. Conventional multilayer optical films with alternating layers of at least one first polymer and one second polymer may be employed in creating the reflective backsheet or film. By selecting the appropriate layer pairs with appropriate refractive indices, the layer thickness, and/or the number of layer pairs, the optical stack can be designed to transmit or reflect desired wavelengths of light.

By appropriate selection of the first optical layers and the second optical layers, the reflective backsheet or a reflective film in the photovoltaic modules disclosed herein can be designed to reflect or transmit a desired bandwidth of light. Reflection is generated at each interface between optical layers in an optical stack, which layers have refractive indices that are different, n₁ and n₂, respectively. Light that is not reflected at the interface of adjacent optical layers typically passes through successive layers and is either absorbed in a subsequent optical layer, reflected at a subsequent interface, or is transmitted through the optical stack altogether. Typically, the optical layers of a given layer pair are selected such as to be substantially transparent to those light wavelengths at which reflectivity is desired. Light that is not reflected at a layer pair interface passes to the next layer pair interface where a portion of the light is reflected and unreflected light continues on, and so on. Increasing the number of optical layers in the optical stack may provide more optical power. In this way, an optical layer stack with many optical layers is capable of generating a high degree of reflectivity. For example, if the refractive index between the layer pairs is small, the optical stack may not achieve the desired reflectivity, however by increasing the number of layer pairs, sufficient reflectivity may be achieved. In some embodiments of the present disclosure, the optical stack comprises at least 2 first optical layers and at least 2 second optical layers, at least 5 first optical layers and at least 5 second optical layers, at least 50 first optical layers and at least 50 second optical layers, at least 200 first optical layers and at least 200 second optical layers, at least 500 first optical layers and at least 500 second optical layers, or at least 1000 first optical layers and at least 1000 second optical layers. In general, at least a portion of the first optical layers and at least a portion of the second optical layers are in intimate contact.

In general, the reflectivity of the interface of adjacent optical layers is proportional to the square of the difference in index of refraction of the first optical layer and the second optical layer at the reflecting wavelength. The absolute difference in refractive index between the layer pair (n₁-n₂) is typically 0.1 or larger. Higher refractive index differences between the first optical layer and the second optical layer are useful, for example, for providing higher optical power (e.g., reflectivity), which enables more reflective bandwidth. However, in the present disclosure, the absolute difference between the layer pair may be less than 0.20, less than 0.15, less than 0.10, less than 0.05, or even less than 0.03, depending on the layer pair selected.

The thickness of each layer may influence the performance of the optical stack by either changing the amount of reflectivity or shifting the reflectivity wavelength range. The optical layers typically have an average individual layer thickness of about one quarter of the wavelength or wavelengths to be reflected, and a layer pair thickness of about one half of the wavelength or wavelengths to be reflected. The optical layers can each be a quarter-wavelength thick or the optical layers can have different optical thicknesses, as long as the sum of the optical thicknesses for the layer pair is half of a wavelength (or a multiple thereof). For example, to reflect 800 nanometers (nm) light, the average individual layer thickness would be about 200 nm, and the average layer pair thickness would be about 400 nm. First optical layers and second optical layers may have the same thicknesses. Alternatively, the optical stack can include optical layers with different thicknesses to increase the reflective wavelength range. An optical stack having more than two layer pairs can include optical layers with different optical thicknesses to provide reflectivity over a range of wavelengths. For example, an optical stack can include layer pairs that are individually tuned to achieve optimal reflection of normally incident light having particular wavelengths or may include a gradient of layer pair thicknesses to reflect light over a larger bandwidth. The normal reflectivity for a particular layer pair is primarily dependent on the optical thickness of the individual layers, where optical thickness is defined as the product of the actual thickness of the layer times its refractive index. The intensity of light reflected from the optical layer stack is a function of its number of layer pairs and the differences in refractive indices of optical layers in each layer pair. The ratio n₁d₁/(n₁d₁+n₂d₂) (commonly termed the “f-ratio”) correlates with reflectivity of a given layer pair at a specified wavelength. In the f-ratio, n₁ and n₂ are the respective refractive indices at the specified wavelength of the first and second optical layers in a layer pair, and d₁ and d₂ are the respective thicknesses of the first and second optical layers in the layer pair. By proper selection of the refractive indices, optical layer thicknesses, and f-ratio, one can exercise some degree of control over the intensity of first order reflection.

The equation λ/2=n₁d₁+n₂d₂ can be used to tune the optical layers to reflect light of wavelength λ at a normal angle of incidence. At other angles, the optical thickness of the layer pair depends on the distance traveled through the component optical layers (which is larger than the thickness of the layers) and the indices of refraction for at least two of the three optical axes of the optical layer.

The optical stack in the multilayer optical film useful for the reflective backsheet or reflective film disclosed herein typically includes all or mostly quarter-wave film stacks. In this case, control of the spectrum requires control of the layer thickness profile in the film stack. Layer thickness profiles of such optical stacks can be adjusted to provide for improved spectral characteristics using the axial rod apparatus taught in U.S. Pat. No. 6,783,349 (Neavin et al.) combined with layer profile information obtained with microscopic techniques.

The basic process for layer thickness profile control involves adjustment of axial rod zone power settings based on the difference of the target layer thickness profile and the measured layer profile. The axial rod power increase needed to adjust the layer thickness values in a given feedblock zone may first be calibrated in terms of watts of heat input per nanometer of resulting thickness change of the layers generated in that heater zone. Fine control of the spectrum is possible using 24 axial rod zones for 275 layers. Once calibrated, the necessary power adjustments can be calculated once given a target profile and a measured profile. The procedure may be repeated until the two profiles converge.

Desirable techniques for providing a multilayer optical film with a controlled spectrum include the use of an axial rod heater control of the layer thickness values of coextruded polymer layers as taught in U.S. Pat. No. 6,783,349 (Neavin et al.); timely layer thickness profile feedback during production from a layer thickness measurement tool (e.g., an atomic force microscope, a transmission electron microscope, or a scanning electron microscope); optical modeling to generate the desired layer thickness profile; and making axial rod adjustments based on the difference between the measured layer profile and the desired layer profile.

The layer thickness profile (layer thickness values) of the optical stack may be adjusted to be approximately a linear profile with the first (thinnest) optical layers adjusted to have about a quarter wave optical thickness (index times physical thickness) for the left band edge of the desired reflection bandwidth and progressing to the thickest layers, which may be adjusted to be about a quarter wave thick optical thickness for the right band edge of the desired reflection bandwidth. In some embodiments, two or more multilayer optical films with different reflection bands are laminated together to broaden the reflection band.

Birefringence (e.g., caused by stretching) of optical layers may increase the difference in refractive index of the optical layers in a layer pair. Optical stacks that include layer pairs, which are oriented in two mutually perpendicular in-plane axes are highly efficient reflectors that capable of reflecting an extraordinarily high percentage of incident light depending on, for example, the number of optical layers, f-ratio, and the indices of refraction.

The multilayer optical film in the reflective backsheet or reflective film disclosed herein has a left band edge in a range from 600 nanometers to 900 nanometers. The left band edge is the wavelength at which the multilayer optical film switches from transmitting to reflecting. The reflective backsheet or reflective film may be designed to switch from transmitting to reflecting in the visible range (e.g., in a range from 600 to 700 nm) or in the infrared range (e.g., in a range from 700 to 900 nm). In some embodiments, the multilayer optical film is a color-shifting film. Color-shifting films change color as a function of viewing angle. For example, if the left band edge of the multilayer optical film is about 650 nanometers, against a white background, the film may appear cyan at a zero degree viewing angle and cobalt blue at a shifted viewing angle of 45 to 60 degrees. In another example, if the left band edge of the multilayer optical film is about 720 nanometers, against a white background, the film may appear colorless at a zero degree viewing angle and cyan at a shifted viewing angle of 45 to 60 degrees. For narrow transmission bands (that is, transmission bands in a range of about 100 rim or less), many colors may be seen at successively higher angles of incidence. Further details about color-shifting films may be found, for example, in U.S. Pat. No. 6,531,230 (Weber et al.) and U.S. Pat. No. 6,045,894 (Jonza et al.). As discussed above, color-shifting films may provide the photovoltaic module with a unique and attractive appearance.

In the photovoltaic module according to the present disclosure, the reflective backsheet or reflective film reflects at least a portion of the light in a range of wavelengths that corresponds with the absorption bandwidth of the photovoltaic cell. “At least a portion” includes bandwidths such as at least 25 nm, 50 nm, 100 nm, 150 nm or 200 nm. Suitable photovoltaic cells include those that have been developed with a variety of semiconductor materials. Each type of semiconductor material will have a characteristic band gap energy which causes it to absorb light most efficiently at certain wavelengths of light, or more precisely, to absorb electromagnetic radiation over a portion of the solar spectrum. Exemplary suitable materials useful for making photovoltaic cells and their photovoltaic light absorption band-edge wavelengths include: crystalline silicon single junction (about 400 nm to about 1150 nm), amorphous silicon single junction (about 300 nm to about 720 nm), ribbon silicon (about 350 nm to about 1150 nm), copper indium gallium selenide (CIGS) (about 350 nm to about 1100 nm), cadmium telluride (CdTe) (about 400 nm to about 895 nm), and gallium arsenide (GaAs) multi-junction (about 350 nm to about 1750 nm). The photovoltaic cell may also be a bifacial cell or a dye-sensitized cell. In some embodiments, the photovoltaic cell is a crystalline silicon single junction cell, a ribbon silicon cell, a CIGS cell, a GaAs multi-junction cell, or a CdTe cell. In some embodiments, the photovoltaic cell is a crystalline silicon single junction cell, a ribbon silicon cell, a CIGS cell, or a GaAs cell. In some embodiments, the photovoltaic cell is a crystalline silicon single junction cell. New materials suitable for making photovoltaic cells continue to be developed. In some embodiments, the photovoltaic cell is an organic photovoltaic cell. In some of these embodiments, the organic photovoltaic cell is transparent, which may be beneficial to daylighting for some embodiments of the photovoltaic module disclosed herein.

Typically, in the photovoltaic module according to the present disclosure, at least a portion of the light in a range of wavelengths that corresponds with the absorption bandwidth of the photovoltaic cell includes near infrared wavelengths and optionally longer visible wavelengths of light. In some embodiments, the reflective backsheet or reflective film according to the present disclosure reflects light in at least a portion of the wavelength range of 650 nm to 1100 nm, 650 nm to 1500 nm, 875 nm to 1100 nm, or 900 nm to 1500 nm. For any of these wavelength ranges, the reflective backsheet or reflective film may have an average reflection of at least 30, 40, 50, 60, 70, 80, 90, 95, 97, 98, or 99 percent at a normal angle of incidence. In some embodiments, light outside the range of wavelengths that corresponds with the absorption bandwidth of the photovoltaic cell passes through the reflective backsheet or reflective film. In other embodiments, some of the light outside the range of wavelengths that corresponds with the absorption bandwidth of the photovoltaic cell is absorbed by the reflective backsheet or reflective film, as described below. The selection of multilayer optical films that reflect at least a portion of light in a range of wavelengths that matches selected photovoltaic cells, while reducing radiation adverse to the photovoltaic cell, can significantly enhance the operational efficiency of the photovoltaic cell.

In some embodiments, the reflective backsheet or reflective film in the photovoltaic module disclosed herein transmits visible light. That is, at least a portion of the wavelengths in a range from 400 to 700 nanometers is transmitted. “At least a portion” is meant to comprise not only the entire range of wavelengths between 400 and 700 nanometers, but also a portion of the wavelengths, such as a bandwidth of at least 25 nm, 50 nm, 100 nm, 150 nm or 200 nm. In some embodiments, the multilayer optical film in the reflective backsheet or reflective film has an average visible light transmission of at least 30, 40, 50, 60, 70, 80, 85, 90, 92, or 95 percent. In these embodiments, the transmission may be measured at a normal angle to the multilayer optical film or at a shifted angle of 45 to 60 degrees. In some embodiments, the multilayer optical film has an average visible light transmission of at least 45, 50, 60, 70, 80, 85, 90, 92, or 95 percent at an angle normal to the multilayer optical film. In some embodiments, the multilayer optical film has an average visible light transmission of at least 45, 50, 60, 70, 80, 85, 90, 92, or 95 percent in a wavelength range selected from the group consisting of 400 nanometers to 500 nanometers, 400 nanometers to 600 nanometers, and 400 nanometers to 700 nanometers at a 0 degree angle of incidence (that is, an angle normal to the film).

In many photovoltaic module constructions (e.g., conventional modules on rooftops or building exteriors) transmission to visible light is unnecessary. For example, conventional solar backsheets are often formed on opaque substrates, which may be black or white, for example. In contrast, in some useful embodiments of the present disclosure, the reflective backsheets or reflective film transmits visible light that is useful, for example, for daylighting inside a building or structure. In some of these embodiments, the photovoltaic module according to the present disclosure is installed in a building and allows visible light to enter the building through the backsheet.

The reflective backsheet or reflective film disclosed herein includes a multilayer optical film with first and second optical layers having different indices of refraction. Typically, the first and second optical layers are polymer layers. In this context, the term “polymer” will be understood to include homopolymers and copolymers, as well as polymers or copolymers that may be formed in a miscible blend, for example, by co-extrusion or by reaction, including transesterification. The terms “polymer” and “copolymer” include both random and block copolymers. The polymer in the first optical layer described herein has a higher refractive index than the polymer in the second optical layer. Useful classes of polymers for first optical layers include, in some embodiments, polyesters and polycarbonates.

Polyesters may be derived, for example, from ring-opening addition polymerization of a lactone, or by condensation of a dicarboxylic acid (or derivative thereof such as, for example, a diacid halide or a diester) with a diol. Exemplary dicarboxylic acids include 2,6-naphthalenedicarboxylic acid; terephthalic acid; isophthalic acid; phthalic acid; azelaic acid; adipic acid; sebacic acid; norbornenedicarboxylic acid; bicyclooctanedicarboxylic acid; 1,6-cyclohexanedicarboxylic acid; t-butyl isophthalic acid; trimellitic acid; sodium sulfonated isophthalic acid; 4,4′-biphenyldicarboxylic acid. Acid halides and lower alkyl esters of these acids, such as methyl or ethyl esters may also be used as functional equivalents. The term “lower alkyl” refers, in this context, to alkyl groups having from one to four carbon atoms. Exemplary diols include ethylene glycol; propylene glycol; 1,4-butanediol; 1,6-hexanediol; neopentyl glycol; polyethylene glycol; diethylene glycol; tricyclodecanediol; 1,4-cyclohexanedimethanol; norbornanediol; bicyclooctanediol; trimethylolpropane; pentaerythritol; 1,4-benzenedimethanol; bisphenol A; 1,8-dihydroxybiphenyl; and 1,3-bis (2-hydroxyethoxy)benzene.

In some embodiments, the first optical layer comprises a birefringent polymer. Exemplary polymers useful for forming birefringent optical layers include polyethylene terephthalates (PETs); polyethylene 2,6-naphthalates (PENs); copolyesters derived from naphthalenedicarboxylic acid, an additional dicarboxylic acid, and a diol (coPENs) (e.g., a polyester derived through co-condensation of 90 equivalents of dimethyl naphthalenedicarboxylate, 10 equivalents of dimethyl terephthalate, and 100 equivalents of ethylene glycol); copolyesters derived from terephthalic acid such as those described in U.S. Pat. No. 6,449,093 B2 (Hebrink et al.) or U. S. Pat. App. Publ. No. 2006/0084780 A1 (Hebrink et al.); copolymers of PEN (CoPEN) such as those described in U.S. Pat. No. 6,352,761 (Hebrink et al.) and U.S. Pat. No. 6,449,093 (Hebrink et al.); polyether imides; polyester/non-polyester combinations; polybutylene 2,6-naphthalates (PBNs); modified polyolefin elastomers, thermoplastic elastomers; thermoplastic polyurethanes (TPUs); and syndiotactic polystyrenes (sPSs), which are useful, for example, for their low UV-light absorbance; and combinations thereof. In some embodiments, the first optical layer comprises an acrylic (e.g., poly(methyl methacrylate) (PMMA)), a polyolefin (e.g., polypropylene), a cyclic olefin copolymer, or a combination thereof. Such embodiments may be useful, for example, when the second optical layer comprises a fluoropolymer.

Exemplary specific polymer products that may be useful for the first optical layers include a PET having an inherent viscosity of 0.74 dL/g, available, for example, from Eastman Chemical Company (Kingsport, Tenn.) and PMMA available, for example, under the trade designations “CP71” and “CP80” from Ineos Acrylics, Inc. (Wilmington, Del.).

The second optical layers of the multilayer optical film can be made, for example, from a variety of polymers. The polymer in the second optical layer may have a glass transition temperature compatible with that of the polymer in the first optical layer. In some embodiments, the polymer in the second optical layer has a refractive index similar to the isotropic refractive index of a birefringent polymer useful for making the first optical layers. Exemplary melt-processible polymers useful in the second optical layers include: polyesters (e.g., polycyclohexanedimethylene terephthalate commercially available from Eastman Chemical Co, Kingsport, Tenn.); polysulfones; polyurethanes; polyamides; polyimides; polycarbonates; polydimethylsiloxanes; polydiorganosiloxane polyoxamide block copolymers (OTPs) such as those described in U. S. Pat. Appln. Publ. Nos. 2007/0148474 A1 (Leir et al.) and 2007/0177272 A1 (Benson et al.); fluoropolymers including homopolymers such as polyvinylidene difluoride (PVDFs), copolymers such as copolymers of tetrafluoroethylene, hexafluoropropylene, and vinylidene fluoride (THVs), copolymers of hexafluoropropylene, tetrafluoroethylene, and ethylene (HTEs); copolymers of tetrafluoroethylene and norbornene; copolymers of ethylene and tetrafluoroethylene (ETFEs); copolymers of ethylene and vinyl acetate (EVAs); copolymers of ethylene and chlorotrifluoroethylene (ECTFEs), fluoroelastomers; acrylics such as PMMA (e.g., that available under the trade designations “CP71” and “CP80” from Ineos Acrylics) and copolymers of methyl methacrylate (coPMMAs) (e.g., a coPMMA made from 75 weight percent methyl methacrylate and 25 weight percent ethyl acrylate (available from Ineos Acrylics, Inc., under trade designations “PERSPEX CP63” and a coPMMA formed from methyl methacrylate and n-butyl methacrylate); styrenic polymers; vinyl acetate copolymers (e.g., ethylene vinyl acetate copolymers); copolymers of ethylene and a cyclic olefin (COCs); blend of PMMA and PVDF (e.g., as available from Solvay Polymers, Inc., Houston, Tex., under the trade designation “SOLEF”); polyolefin copolymers such as poly (ethylene-co-octene) (PE-POs) available from Dow Chemical Co., Midland, Mich., under the trade designation “ENGAGE 8200”, poly (propylene-co-ethylene) (PPPE) available from Fina Oil and Chemical Co., Dallas, Tex. under the trade designation “Z9470”, and a copolymer of atactic polypropylene (aPPs) and isotactic polypropylene (iPPs) available from Huntsman Chemical Corp., Salt Lake City, Utah, under the trade designation “REXFLEX W111”; and combinations thereof. Second optical layers can also be made from a functionalized polyolefin such as linear low density polyethylene-g-maleic anhydride (LLDPE-g-MA) (e.g., available from E. I. du Pont de Nemours & Co., Inc., Wilmington, Del. under the trade designation “BYNEL 4105”) or blends of this polymer and others described above.

In some embodiments, polymer compositions suitable for the second optical layers include PMMA, CoPMMA, polydimethyl siloxane oxamide based segmented copolymer (SPOX), fluoropolymers including homopolymers such as PVDF and copolymers such as those derived from tetrafluoroethylene, hexafluoropropylene, and vinylidene fluoride (THVs), blends of PVDF and PMMA, acrylate copolymers, styrene, styrene copolymers, silicone copolymers, polycarbonate, polycarbonate copolymers, polycarbonate blends, blends of polycarbonate and styrene maleic anhydride, and cyclic-olefin copolymers. In some embodiments, the second optical layers comprise poly(methyl methacrylate), copolymers of methyl methacrylate and other acrylate monomers, or blends of poly(methyl methacrylate) and poly(vinylidene difluoride).

The selection of the polymer compositions used in creating the multilayer optical film will depend upon the desired bandwidth that will be reflected onto a chosen photovoltaic cell. Higher refractive index differences between the polymers in the first and the second optical layers create more optical power thus enabling more reflective bandwidth. Alternatively, additional layers may be employed to provide more optical power. Exemplary useful combinations of first and second polymer layers include polyethylene terephthalate with copolymers of tetrafluoroethylene, hexafluoropropylene, and vinylidene fluoride; polyethylene terephthalate with polydimethyl siloxane oxamide based segmented copolymer, polyethylene terephthalate with poly(methyl methacrylate); polyethylene terephthalate with a polyvinylidene difluoride and poly(methyl methacrylate) blend; polyethylene 2,6-naphthalate with copolymers of tetrafluoroethylene, hexafluoropropylene, and vinylidene fluoride; polyethylene 2,6-naphthalate with polydimethyl siloxane oxamide based segmented copolymer; polyethylene 2,6-naphthalate with poly(methyl methacrylate); polyethylene terephthalate with copolymers of methyl methacrylate; polyethylene 2,6-naphthalate with copolymers of methyl methacrylate; copolymers of polyethylene 2,6-naphthalate with poly(methyl methacrylate); copolymers of polyethylene 2,6-naphthalate with polydimethyl siloxane oxamide based segmented copolymer; syndiotactic polystyrene with polydimethyl siloxane oxamide based segmented copolymer; syndiotactic polystyrene with copolymers of tetrafluoroethylene, hexafluoropropylene, and vinylidene fluoride; copolymers of polyethylene 2,6-naphthalate with copolymers of tetrafluoroethylene, hexafluoropropylene, and vinylidene fluoride; polyethylene terephthalate with fluoroelastomers; syndiotactic polystyrene with fluoroelastomers; copolymers of polyethylene 2,6-naphthalate with fluoroelastomers; and poly(methyl methacrylate) with copolymers of tetrafluoroethylene, hexafluoropropylene, and vinylidene fluoride.

Further considerations relating to the selection of materials and manufacturing of optical stacks and multilayer optical films are described in U.S. Pat. No. 5,552,927 (Wheatley et al.); U.S. Pat. No. 5,882,774 (Jonza et al.); U.S. Pat. No. 6,827,886 (Neavin et al.); U.S. Pat. No. 6,830,713 (Hebrink et al.); and U.S. Pat. No. 7,141,297 (Condo et. al.); and in Int. Pat. App. Pub. No. WO 2010/078289 (Hebrink et al.).

In some embodiments, the reflective film or reflective backsheet comprises an ultraviolet light-protective layer (UV-protective layer) applied onto at least one surface of the multilayer optical film. In some embodiments, a UV-protective layer may be applied to both surfaces. A UV-protective layer typically shields the multilayer optical film from UV radiation that may cause degradation. In particular, the ultraviolet radiation from 280 nm to 400 nm can induce degradation of plastics, which in turn results in color change and deterioration in mechanical properties Inhibition of photo-oxidative degradation is useful for outdoor applications wherein long term durability is desired. The absorption of UV light by polyethylene terephthalates, for example, starts at around 360 nm, increases markedly below 320 nm and is very pronounced at below 300 nm. Polyethylene naphthalates strongly absorb UV light in the 310-370 nm range, with an absorption tail extending to about 410 nm, and with absorption maxima occurring at 352 nm and 337 nm. Chain cleavage occurs in the presence of oxygen, and the predominant photooxidation products are carbon monodioxide, carbon dioxide, and carboxylic acids. Besides the direct photolysis of the ester groups, consideration has to be given to oxidation reactions which likewise form carbon dioxide via peroxide radicals.

Useful UV-protective layers may shield the multilayer optical film by reflecting UV light, absorbing UV light, scattering UV light, or a combination thereof. Useful UV protective layers may include a polymer or combination of polymers that is capable of withstanding UV radiation for an extended period of time while either reflecting, scattering, or absorbing UV radiation. Non-limiting examples of such polymers include poly(methyl methacrylate), silicone thermoplastics, fluoropolymers, and their copolymers, and blends thereof. An exemplary UV-protective layer comprises a blend of poly(methylmethacryate) and polyvinylidene difluoride.

A variety of optional additives may be incorporated into the UV protective layer to assist in its function of protecting the multilayer optical film. Non-limiting examples of the additives include one or more compounds selected from ultraviolet light absorbers, hindered amine light stabilizers, anti-oxidants, and combinations thereof.

UV stabilizers such as UV absorbers are chemical compounds which can intervene in the physical and chemical processes of photo-induced degradation. The photooxidation of polymers from UV radiation can therefore be prevented by use of a protective layer containing UV absorbers to effectively block UV light. UV absorbers are typically included in the UV-absorbing layer in an amount that absorb at least 70 percent, typically 80 percent, more typically greater than 90 percent, or even greater than 99 percent of incident light in a wavelength region from 180 to 400 nm. UV absorbers may be red-shifted UV absorbers, which have enhanced spectral coverage in the long-wave UV region, enabling it to block the high wavelength UV light that can cause yellowing in polyesters. Typical UV-protective layer thicknesses are from 10 microns to 500 microns although thick and thinner UV-absorbing layers can be useful in some applications. Typically, the UV-absorber is present in the UV-absorbing layer in an amount of from 2 to 20 percent by weight, but lesser and greater levels may also be useful for some applications. In some embodiments, the ultraviolet light protective layer comprises poly(vinylidene difluoride), poly(methyl methacrylate), and an ultraviolet light absorber.

One exemplary UV absorber is a benzotriazole compound, 5-trifluoromethyl-2-(2-hydroxy-3-alpha-cumyl-5-tert-octylphenyl)-2H-benzotriazole. Other exemplary benzotriazoles include 2-(2-hydroxy-3,5-di-alpha-cumylphehyl)-2H-benzotriazole, 5-chloro-2-(2-hydroxy-3-tert-butyl-5-methylphenyl)-2H-benzotiazole, 5-chloro-2-(2-hydroxy-3,5-di-tert-butylphenyl)-2H-benzotriazole, 2-(2-hydroxy-3,5-di-tert-amylphenyl)-2H-benzotriazole, 2-(2-hydroxy-3-alpha-cumyl-5-tert-octylphenyl)-2H-benzotriazole, and 2-(3-tert-butyl-2-hydroxy-5-methylphenyl)-5-chloro-2H-benzotriazole. Additional exemplary UV absorbers include 2-(4,6-diphenyl-1,3,5-triazin-2-yl)-5-hexcyloxyphenol, a diphenyl triazine available under the trade designation “CGXUVA 006” from BASF, Florham Park, N.J.), and those available from Ciba Specialty Chemicals Corp., Tarrytown, N.Y., under the trade designations “TINUVIN 1577” and “TINUVIN 900”. In addition, UV absorber(s) can be used in combination with hindered amine light stabilizer(s) (HALS) and/or antioxidants. Exemplary HALSs include those available from Ciba Specialty Chemicals Corp. under the trade designations “CHIMASSORB 944” and “TINUVIN 123”. Exemplary antioxidants include those available under the trade designations “IRGANOX 1010” and “ULTRANOX 626” from Ciba Specialty Chemicals Corp.

Other additives may be included in the UV-absorbing layer. Small particle non-pigmentary zinc oxide and titanium oxide can also be used as blocking or scattering additives in the UV-absorbing layer. For example, certain nanometer-scale particles can be dispersed in polymer or coating substrates to minimize ultraviolet radiation degradation. The nanoparticles are transparent to visible light while either scattering or absorbing harmful UV radiation thereby reducing damage to thermoplastics. U.S. Pat. No. 5,504,134 (Palmer et al.), for example, describes attenuation of polymer substrate degradation due to ultraviolet radiation through the use of metal oxide particles in a size range of about 0.001 micrometer to about 0.20 micrometer in diameter, and, in some embodiments, from about 0.01 to about 0.15 micrometers in diameter. U.S. Pat. No. 5,876,688 (Laundon) describes a method for producing micronized zinc oxide particles that are small enough to be transparent when incorporated as UV blocking and/or scattering agents in paints, coatings, finishes, plastic articles, and cosmetics. These fine particles such as zinc oxide and titanium oxide with particle size ranged from 10 nm to 100 nm, which can attenuate UV radiation, are commercially available, for example, from Kobo Products, Inc., South Plainfield, N.J. Flame retardants may also be incorporated as an additive in the UV-absorbing layer.

The thickness of the ultraviolet light protective layer is dependent upon an optical density target at specific wavelengths as calculated by the Beer-Lambert Law. In typical embodiments, the ultraviolet light absorbing layer has an optical density greater than 3.5 at 380 nm; greater than 1.7 at 390 nm; and greater than 0.5 at 400 nm. Those of ordinary skill in the art will recognize that the optical densities must remain fairly constant over the extended life of the article in order to provide the intended protective function.

In some embodiments, the ultraviolet light-protective layer is a multilayer ultraviolet light reflective mirror (multilayer UV-reflective mirror). The multilayer UV-reflective mirror is reflective to UV light; for example, it is at least 30, 40, 50, 60, 70, 80, 90, or 95 percent reflective to at least a portion of UV light at a normal angle of incidence. The multilayer ultraviolet light reflective mirror is typically a multilayer optical film that reflects wavelengths of light from about 350 to about 400 nm, or, in some embodiments, from 300 nm to 400 nm. In some embodiments, these wavelengths are included in the absorption bandwidth of the photovoltaic cell. The multilayer ultraviolet light reflective mirror can be made according to the techniques described above for making multilayer optical films except that the polymers for the layer pairs (e.g., third and fourth optical layers in some embodiments), layer thicknesses, and number of layers are selected to reflect UV light. The polymers that make the multilayer optical film are typically selected such that they do not absorb UV light in the 300 nm to 400 nm range. Exemplary suitable pairs of polymers useful for preparing multilayer UV reflective mirrors include polyethylene terephthalate with a tetrafluoroethylene, hexafluoropropylene, and vinylidene fluoride copolymer; poly(methyl methacrylate) with tetrafluoroethylene, hexafluoropropylene, and vinylidene fluoride copolymer; polyethylene terephthalate with SPOX; poly(methyl methacrylate) with SPOX; syndiotactic polystyrene with tetrafluoroethylene, hexafluoropropylene, and vinylidene fluoride copolymer; syndiotactic polystyrene with SPOX; modified polyolefin copolymers (e.g., EVA) with a tetrafluoroethylene, hexafluoropropylene, and vinylidene fluoride copolymer; a thermoplastic polyurethane with a tetrafluoroethylene, hexafluoropropylene, and vinylidene fluoride copolymer; and a thermoplastic polyurethane with SPOX. In some embodiments, a blend of tetrafluoroethylene, hexafluoropropylene, and vinylidene fluoride copolymer obtained under the trade designation “DYNEON THV” (e.g., 220 grade or 2030 grade), from Dyneon LLC, Oakdale, Minn., is employed with PMMA for multilayer UV mirrors reflecting 300-400 nm or with PET for multilayer mirrors reflecting 350-400 nm. In general, 100 to 1000 total layers of the polymer combinations are suitable for use with the present disclosure. Examples of multilayer UV light reflective mirrors can be found, for example, in Int. Pat. App. Pub. No. WO 2010/078105 (Hebrink et al.).

In some embodiments wherein the multilayer optical film of the reflective backsheet or reflective film disclosed herein comprises a multilayer UV-reflective mirror, the multilayer UV-reflective mirror comprises a UV absorber, including any of the UV absorbers described above. The UV absorber may be, for example, in one or more of the optical layers or in one or more non-optical skin layers on either side of the optical layer stack of the multilayer UV-reflective mirror.

While UV absorbers, HALS, nanoparticles, flame retardants, and anti-oxidants can be added to a UV protective layer, in other embodiments UV absorbers, HALS, nanoparticles, flame retardants, and anti-oxidants can be added to the multilayer optical layers themselves and/or optional non-optical skin layers or durable top coat layers. Fluorescing molecules and optical brighteners can also be added to a UV protective layer, the multilayer optical layers, an optional durable top coat layer, or a combination thereof.

In some embodiments, including embodiments in which the multilayer optical film in the reflective backsheet or reflective film includes a UV protective layer as described in any of the above embodiments, the reflective backsheet or reflective film exhibits resistance to degradation by UV light. Resistance to degradation by UV light can be determined using the weathering cycle described in ASTM G155 and a D65 light source operated in the reflected mode. In some embodiments, under the noted test, the reflective backsheet or reflective film does not change substantially in color, haze, or transmittance and does not significantly crack, peel, or delaminate. In some embodiments, after exposure of at least 18,700 kJ/m² at 340 nm, the b* value obtained using the CIE L*a*b* scale of the reflective backsheet or reflective film increases by 10 or less, 5 or less, 4 or less, 3 or less, or 2 or less. In some embodiments, after exposure of at least 18,700 kJ/m² at 340 rim, the reflective backsheet or reflective film exhibits a difference in haze versus the initial haze of up to 20, 15, 10, 5, 2, or 1 percent. In some embodiments, after exposure of at least 18,700 kJ/m² at 340 nm, the reflective backsheet or reflective film exhibits a difference in transmission versus the initial transmission of up to 20, 15, 10, 5, 2, or 1 percent.

In some embodiments, particularly embodiments in which the multilayer optical film in the reflective backsheet or reflective film disclosed herein is transmissive to visible light, the UV-protective layer is also at least partially visible light-transmissive.

In some embodiments, the reflective backsheet or reflective film disclosed herein may include a layer including infrared absorbing particles to absorb at least some of the infrared light that is not reflected. The infrared absorbing particles may be included in some of the optical layers or in non-optical skin layers, for example, of the multilayer optical film. The infrared radiation absorbing nanoparticles may include any material that preferentially absorbs infrared radiation. Examples of suitable materials include metal oxides such as tin, antimony, indium and zinc oxides and doped oxides. In some embodiments, the metal oxide nanoparticles include, tin oxide, antimony oxide, indium oxide, indium doped tin oxide, antimony doped indium tin oxide, antinomy tin oxide, antimony doped tin oxide or mixtures thereof. In some embodiments, the metal oxide nanoparticles include antimony oxide (ATO) and/or indium tin oxide (ITO). It may be useful to include infrared absorbing particles, for example, in applications where the photovoltaic module transmits visible light and is installed in a building or other structure. In these applications, the infrared absorbing particles may prevent at least some of the non-reflected infrared light from entering the building or structure.

In some embodiments, the multilayer optical film in the reflective backsheet or reflective film disclosed herein includes tie layers, for example, to attach two multilayer optical films with different reflection bandwidths or to attach the multilayer optical film to the UV-protective layer in any of its embodiments. The optional tie layer may facilitate adhesion of the films and provide long term stability while the photovoltaic module of the present disclosure is in use and exposed to outdoor elements.

The optional tie layer may be organic (e.g., a polymeric layer or adhesive), inorganic, or a combination thereof. Exemplary inorganic tie layers include amorphous silica, silicon monoxide, and metal oxides (e.g., tantalum pentoxide, titanium dioxide, and aluminum oxide). The tie layer may be provided by any suitable means, including vapor coating, solvent casting, and powder coating techniques. In some embodiments, the optional tie layer is typically substantially not absorptive of light (e.g., having an absorbance of less than 0.1, less than 0.01, less than 0.001, or less than 0.0001) over the wavelength range of from 400 to 2494 nm. Useful adhesive tie layers include pressure-sensitive adhesives, thermosetting adhesives, hot melt adhesives, and combinations thereof. Exemplary useful adhesive tie layers include optically clear acrylic pressure sensitive adhesives (25 micrometer thickness) available from 3M Company, St. Paul, MN as “OPTICALLY CLEAR LAMINATING ADHESIVE 8141” or as “OPTICALLY CLEAR LAMINATING ADHESIVE 8171”; tackified OTP adhesives as described in U.S. Pat. No. 7,371,464 B2 (Sherman et al.); and non-silicone pressure-sensitive adhesives as described in for example, in U.S. Pat. Appl. Pub. No. 2011/0123800 (Sherman et al.). Further examples of tie layers include SPOX, CoPETs including modifications such as with functional groups sulfonic acids, PMMA/PVDF blends, modified olefins with functional comonomers such as maleic anhydride, acrylic acid, methacrylic acid or vinyl acetate. Additionally, UV or thermally curable acrylates, silicones, epoxies, siloxanes, urethane acrylates may be suitable as tie layers. The tie layers may optionally contain UV absorbers as described above and may optionally contain conventional plasticizers, tackifiers, or combinations thereof. The tie layer may be applied utilizing conventional film forming techniques. In some embodiments, the tie layers are at least partially transmissive to visible light.

In some embodiments, the multilayer optical film in the reflective backsheet or reflective film disclosed herein includes a durable top coat to assist in preventing the premature degradation due to exposure to outdoor elements. The durable topcoat is typically abrasion and impact resistant and does not interfere with the reflection of a selected bandwidth of light corresponding to the absorption bandwidth of the photovoltaic cell. Durable top coat layers may include one or more of the following non-limiting examples, PMMA/PVDF blends, thermoplastic polyurethanes, curable polyurethanes, CoPET, cyclic olefin copolymers (COC's), fluoropolymers and their copolymers such as PVDF, ETFE, FEP, and THV, thermoplastic and curable acrylates, cross-linked acrylates, cross-linked urethane acrylates, cross-linked urethanes, curable or cross-linked polyepoxides, and SPOX. Strippable polypropylene copolymer skins may also be employed. Alternatively, silane silica sol copolymer hard coating can be applied as a durable top coat to improve scratch resistance. The durable top coat may contain UV absorbers, HALS, and anti-oxidants as described above. The durable top coat may be curable at an elevated temperature (e.g., 80° C.) for 15 to 30 minutes.

A variety of methods may be useful for evaluating the impact or abrasion resistance of the durable top coat. Taber abrasion is one test to determine a film's resistance to abrasion, and resistance to abrasion is defined as the ability of a material to withstand mechanical action such as rubbing, scrapping, or erosion. According to the ASTM D1044 test method, a 500-gram load is placed on top of CS-10 abrader wheel and allowed to spin for 50 revolutions on a 4 square inch test specimen. The reflectivity of the sample before and after the Taber abrasion test is measured, and results are expressed by changes in % reflectivity. In some embodiments, the change in % reflectivity is expected to be less than 20%, less than 10%, or less than 5%. Other suitable tests for mechanical durability include break elongation, pencil hardness, sand blast test, and sand shaking abrasion. The durable top coat may also enhance the resistance to weathering of the reflective backsheet or reflective film, which may be evaluated by ASTM G155 as described above.

In some embodiments, the multilayer optical film in the reflective backsheet or reflective film disclosed herein comprises an antisoiling top coat. In some embodiments, the durable top coat described includes at least one antisoiling component. Examples of antisoiling components include fluoropolymers, silicone polymers, titanium dioxide particles, polyhedral oligomeric silsesquioxanes (e.g., as available as POSS from Hybrid Plastics of Hattiesburg, Miss.), and combinations thereof. In some embodiments, the antisoiling coating may be a hydrophobic coating which includes a polymer matrix (e.g., a silicone or fluoropolymer) and nanoparticles dispersed therein. The nanoparticles may be, for example, polymer (e.g., fluoropolymer) particles, particles of a dielectric material (e.g., silica, alumina, zirconia, titania, or indium tin oxide particles), or metal (e.g., gold) particles. Further details regarding such hydrophobic coatings are described, for example, in Int. Pat. Appl. Pub. Nos. 2012/058090 and 2012/058086, both to Zhang et al., the disclosures of which are incorporated by reference herein. In some embodiments, the antisoiling coating may comprise nanosilica and may be coated out of water. Further details of such coatings are described in Int. Pat. Appl. Pub. Nos. 2012/047867 and 2012/047877, both to Brown et al., the disclosures of which are incorporated by reference herein.

In some embodiments, the backsheet or reflective backsheet comprises a visible light-transmitting substrate. Suitable substrates include glass sheets, polymeric sheets, polymer fiber composites, and glass fiber composites. Also, optionally a UV absorber, such as any of those previously described, may be included in the substrate. Referring to the exemplary constructions shown in FIGS. 1 and 2, the same substrate may be useful, for example, for the optional front cover 10 and the backsheet substrate 6. One exemplary substrate material is twin wall polycarbonate sheeting, e.g., as available under the trade designation “SUNLITE MULTIWALL POLYCARBONATE SHEET” from Palram Americas, Inc. of Kutztown, PA. In other embodiments, the visible light-transmitting substrate may be acrylic sheeting, for example, as available under the trade designation “PLEXIGLAS” from Arkema, Inc, Philadelphia, PA. In any of these embodiments, the visible light-transmitting substrate need not be completely transparent.

The substrate and the multilayer optical film useful in the photovoltaic modules disclosed herein may also be translucent and still allow visible light into a building or other structure, for example. However, for embodiments in which the photovoltaic module is useful for daylighting, the substrate should not be provided with any coating or sheeting that would destroy the visible light-transmitting properties of the module. For example, no opaque white, black, or metallic film or paint should be applied on the substrate or the multilayer optical film in such embodiments.

In some embodiments, the photovoltaic module according to the present disclosure is formed as an architectural article that can be integrated into a building or other structure. For example, the architectural article may be a window, a skylight, a covering or partial covering such as a roof or an awning, an atrium, a door, or a combination thereof. The roof may be, for example, on a building, parking lot, or carport. Advantageously, in embodiments wherein the photovoltaic module is transmissive to visible light, when the architectural article is installed as part of a building or structure, the photovoltaic module allows visible light to enter into the building or structure (that is, it allows daylighting).

In some embodiments, the backsheet, which in some embodiments is a reflective backsheet, is planar. The reflective backsheet, for example, may occupy a plane that is completely underneath a plane occupied by the photovoltaic cells. In embodiments wherein a reflective film is positioned over the backsheet, the reflective film, which may be cut into portions, may occupy a plane different from a plane occupied by the photovoltaic cells or it may be coplanar with the photovoltaic cells. In some embodiments, the multilayer optical film in the photovoltaic module occupies only one planar (that is, it is planar). This means, for example, that the multilayer optical film is not formed into multiple reflective surfaces that reflect onto the plurality of photovoltaic cells. When the multilayer optical film in the photovoltaic module is planar, it can also mean that the multilayer optical film is not thermoformed (e.g., as described in U.S. Pat. No. 6,788,463 (Merrill et al.)).

In some embodiments, the photovoltaic module according to the present disclosure may enhance the efficiency of photovoltaic cells due to a reduction in the non-useful bandwidth (e.g., in the infrared) reflected on the cell. This reduction in reflected bandwidth helps to minimize the overheating of the photovoltaic cell. Furthermore, the reflective backsheet or reflective film may provide an increased power output that results in lower costs per produced energy ($/Watt). In some embodiments, the reflective backsheet or the reflective film is a specular reflector. In other embodiments, the reflective backsheet or reflective film is a diffuse reflector.

The power output of the photovoltaic module may be enhanced by providing the multilayer optical film with a textured surface. Incident solar rays are reflected off the sloped surfaces of the textured surface. These reflected solar rays reflect onto an adjacent surface structure where they are either refracted directly to the solar energy conversion device, or are totally internally reflected to the solar energy conversion device, for example, by being reflected off of the front cover layer. Almost all of the incident solar rays eventually reach the solar energy conversion device, thus increasing its efficiency.

Exemplary textured surfaces comprise a series of structures. In some embodiments, a textured surface is provided on a multilayer optical film, for example, by an embossing roll. In other embodiments, a textured surface is provided with a textured layer on the multilayer optical film as shown in FIG. 4. FIG. 4 schematically illustrates a backsheet 100 useful in some embodiments of the photovoltaic module according to the present disclosure. The backsheet 100 includes optional substrate 105, multilayer optical film 103, and textured layer 109.

The textured layer 109 may be a single material or may be a multilayer construction, where the textured layer comprises one material formulation, and a base film and adhesive comprise different material formulations. Additionally, the film and adhesive layers could themselves comprise multiple layers. Generally, the textured layer has a structured surface wherein a substantial portion of reflected light intersects another structure on the surface. In some embodiments, the series of structures comprises a series of essentially parallel peaks separated by a series of essentially parallel valleys. In cross-section the textured layer may assume a variety of wave forms. For example, the cross section may assume a symmetric saw tooth pattern in which each of the peaks are identical as are each of the valleys; a series of parallel peaks that are of different heights, separated by a series of parallel valleys; or a saw tooth pattern of alternating, parallel, asymmetric peaks separated by a series of parallel, asymmetric valleys. In some embodiments, the peaks and valleys are continuous and in other embodiments a discontinuous pattern of peaks and valleys is also contemplated. Thus, for example, the peaks and valleys may terminate for a portion of the article. The valleys may either narrow or widen as the peak or valley progresses from one end of the article to the other. Still further, the height and/or width of a given peak or valley may change as the peak or valley progresses from one end of the article to the other.

The dimensions of the peaks generally have a height of at least about 10 micrometers (0.0004 inch). In some embodiments, peaks have a height up to about 250 micrometers (0.010 inch). In one embodiment, for example, the peaks are at least about 20 micrometers (0.0008 inch) high, and in another exemplary embodiment, the peaks are up to about 150 micrometers (0.006 inch) high. The peak-to-peak spacing between adjacent peaks is generally at least about 10 micrometers (0.0004 inch). In another embodiment, the spacing is up to about 250 micrometers (0.010 inch). In one embodiment, the spacing is at least about 20 micrometers (0.0008 inch), and in some embodiments, the spacing is as much as about 150 micrometers (0.006 inch). The included angle between adjacent peaks can also vary. The valleys may be flat, round, parabolic, or V-shaped. The peaks are generally V-shaped and have an apex angle of greater than 90 degrees (in some embodiments greater than 100 degrees, or even greater than 120 degrees). The present application is also directed to peaks having a radius of curvature at the tip, and such an embodiment has an apex angle measured by the best fit line to the sides.

In some embodiments, the series of structures are non-uniform structures. For example, the structures differ in height, base width, pitch, apex angle, or other structural aspect. In such embodiments, the slope of the structures from the plane of the surface averages over the surface less than 30 degrees from horizontal. In other embodiments, for example, the structures are substantially symmetric in one dimension around a perpendicular to the surface.

The textured surface can comprise, for example, a high refractive index acrylate, a nanozirconia filled acryalte such as that described in U.S. Pat. No. 7,833,621 (Jones et al.) the examples of which are incorporated herein by reference, a coPEN, a fluoropolymer, or a polyurethane. The refractive index of the textured surface layer is typically at least 0.05 greater than the refractive index of the encapsulant or 0.05 less than the refractive index of the encapsulant. In some embodiments, where the encapsulant used in the photovoltaic module is EVA, the refractive index of the textured surface layer is at least 1.55 or at most 1.45. The reaction mixture may also contain additional components which are not condensation polymerizable, and generally contains at least one UV stabilizer. The curing of the polymer, for example, can be carried out in a mold or tool to generate the textured surface in the cured surface.

Further enhancements in photovoltaic cell power output may be achieved when anti-reflective surface structured films or coatings are applied to the front surface of the cell in an photovoltaic module disclosed herein. Surface structures in the films or coating typically change the angle of incidence of light such that it enters the polymer and cell beyond the critical angle and is internally reflected, leading to more absorption by the cell. Such surface structures can be in the shape, for example, of linear prisms, pyramids, cones, or columnar structures. For prisms, typically the apex angle of the prisms is less than 90 degrees (e.g., less than 60 degrees). The refractive index of the surface structured film or coating is typically less than 1.55 (e.g., less than 1.50). These anti-reflective surface structured films or coatings can be made durable and easily cleanable with the use of inherently UV stable and hydrophobic or hydrophilic materials. Durability can be enhanced with the addition of inorganic nano-particles.

The photovoltaic module disclosed herein may be further applied with other conventional solar collection devices. For example, thermal transfer devices may be applied to either collect energy from the photovoltaic cell or dissipate heat from the photovoltaic cell. Conventional thermal heat sinks include thermally conductive materials that include ribs, pins or fins to enhance the surface area for heat transfer.

The thermally conductive materials include metals or polymers modified with fillers to improve the thermal conductivity of the polymer. Thermally conductive adhesives (e.g., a thermally conductive adhesive available from 3M Company under the trade designation “3M TC-2810”) may be used to attach photovoltaic cells to thermal transfer devices. Additionally, conventional heat transfer fluids, such as water, oils or fluoroinert heat transfer fluids may be employed as thermal transfer devices.

In some embodiments, the photovoltaic module according to the present disclosure can be placed on celestial tracking devices. At least one of the photovoltaic cell or the visible light-transmitting reflector can be connected to one or more celestial tracking mechanisms. The photovoltaic module may be pivotally mounted on a frame. The pivotally mounted module may pivot, for example, in one direction or in two directions. Movement of celestial trackers in any of the above embodiments can be controlled by a number of mechanisms (e.g., piston driven levers, screw driven levers or gears, pulley driven cables, and cam systems). Software can also be integrated with the tracking mechanism based on GPS coordinates to optimize the position of the mirrors.

### Some Embodiments of the Disclosure

In a first embodiment, the present disclosure provides photovoltaic module comprising:

a reflective backsheet comprising a multilayer optical film having an optical stack comprising a plurality of alternating first and second optical layers with different indices of refraction and having a left band edge in a range from 600 nanometers to 900 nanometers; and

a plurality of photovoltaic cells overlying the reflective backsheet, wherein the plurality of photovoltaic cells are spaced apart from each other such that open areas of the reflective backsheet are not covered by the plurality of photovoltaic cells;

wherein photovoltaic cells have an absorption bandwidth, and wherein the multilayer optical film reflects at least a portion of light in a range of wavelengths that corresponds with the absorption bandwidth of the photovoltaic cell.

In a second embodiment, the present disclosure provides the photovoltaic module of the first embodiment, wherein the multilayer optical film is a color-shifting film having a left band edge in a range from 600 to 750 nanometers.

In a third embodiment, the present disclosure provides the photovoltaic module of the first or second embodiment, wherein the multilayer optical film has an average visible light transmission of at least 30 percent.

In a fourth embodiment, the present disclosure provides the photovoltaic module of the third embodiment, wherein the multilayer optical film has an average visible light transmission of at least 45 percent at an angle normal to the multilayer optical film.

In a fifth embodiment, the present disclosure provides the photovoltaic module of the third embodiment, wherein the multilayer optical film has an average visible light transmission of at least 45 percent in a wavelength range selected from the group consisting of 400 nanometers to 500 nanometers, 400 nanometers to 600 nanometers, and 400 nanometers to 700 nanometers.

In a sixth embodiment, the present disclosure provides the photovoltaic module of any one of the first to fifth embodiments, wherein the multilayer optical film has an average light reflection of at least 50 percent at a normal angle to the multilayer optical film in a wavelength range selected from the group consisting of 650 nanometers to 1100 nanometers, 650 nanometers to 1500 nanometers, 875 nanometers to 1100 nanometers, and 875 nanometers to 1500 nanometers.

In a seventh embodiment, the present disclosure provides the photovoltaic module of any one of the first to sixth embodiments, wherein the multilayer optical film has an average light transmission of at least 50 percent for wavelengths above 1200 nanometers at a normal angle to the multilayer optical film.

In an eighth embodiment, the present disclosure provides the photovoltaic module of any one of the first to seventh embodiments, wherein the reflective backsheet is a specular reflector.

In a ninth embodiment, the present disclosure provides the photovoltaic module of any one of the first to seventh embodiments, wherein the reflective backsheet is a diffuse reflector.

In a tenth embodiment, the present disclosure provides the photovoltaic module of any one of the first to ninth embodiments, wherein the photovoltaic cell is a crystalline silicon single junction cell, a ribbon silicon cell, a copper indium gallium selenide cell, or a gallium arsenide cell.

In an eleventh embodiment, the present disclosure provides the photovoltaic module of any one of the first to tenth embodiments, wherein the first optical layers comprise polyethylene terephthalate.

In a twelfth embodiment, the present disclosure provides the photovoltaic module of any one of the first to eleventh embodiments, wherein the second optical layers comprise poly(methyl methacrylate), copolymers of methyl methacrylate and other acrylate monomers, or blends of poly(methyl methacrylate) and poly(vinylidene difluoride).

In a thirteenth embodiment, the present disclosure provides the photovoltaic module of any one of the first to twelfth embodiments, further comprising an ultraviolet light protective layer on at least one surface of the multilayer optical film.

In a fourteenth embodiment, the present disclosure provides the photovoltaic module of the thirteenth embodiment, wherein the ultraviolet light protective layer comprises poly(vinylidene difluoride), poly(methyl methacrylate), and an ultraviolet light absorber.

In a fifteenth embodiment, the present disclosure provides the photovoltaic module of the thirteenth or fourteenth embodiment, wherein the ultraviolet light protective layer is a multilayer ultraviolet light reflective mirror.

In a sixteenth embodiment, the present disclosure provides the photovoltaic module of any one of the first to fifteenth embodiments, wherein the reflective backsheet comprises a visible light-transmitting substrate.

In a seventeenth embodiment, the present disclosure provides the photovoltaic module of the sixteenth embodiment, wherein the photovoltaic module is installed as part of a building and allows visible light to enter the building through the reflective backsheet.

In an eighteenth embodiment, the present disclosure provides the photovoltaic module of the sixteenth or seventeenth embodiment, wherein the photovoltaic module forms at least a portion of a window, a skylight, or a door.

In a nineteenth embodiment, the present disclosure provides the photovoltaic module of the sixteenth or seventeenth embodiment, wherein the photovoltaic module forms at least a portion of a roof.

In a twentieth embodiment, the present disclosure provides the photovoltaic module of the sixteenth or seventeenth embodiment, wherein the photovoltaic module is installed in an awning.

In a twenty-first embodiment, the present disclosure provides the photovoltaic module of the sixteenth or seventeenth embodiment, wherein the photovoltaic module is installed in an atrium.

In a twenty-second embodiment, the present disclosure provides the photovoltaic module of any one of the first to fifteenth embodiments, the backsheet comprises an opaque substrate.

In a twenty-third embodiment, the present disclosure provides the photovoltaic module of the twenty-second embodiment, wherein the opaque substrate is black.

In a twenty-fourth embodiment, the present disclosure provides the photovoltaic module of the twenty-second embodiment, wherein the opaque substrate is white.

In a twenty-fifth embodiment, the present disclosure provides the photovoltaic module of any one of the first to twenty-fourth embodiments, wherein the reflective backsheet is planar.

In a twenty-sixth embodiment, the present disclosure provides the photovoltaic module of any one of the first to twenty-fifth embodiments, wherein the multilayer optical film comprises a textured surface.

In a twenty-seventh embodiment, the present disclosure provides the photovoltaic module of the twenty-sixth embodiment, wherein the photovoltaic module further comprises an encapsulant, and wherein the multilayer optical film has a textured layer on its surface with a refractive index that is at least 0.05 different than the encapsulant.

In a twenty-eighth embodiment, the present disclosure provides the photovoltaic module of any one of the first to twenty-seventh embodiments, further comprising an anti-soiling coating on at least one surface of the multilayer optical film.

In a twenty-ninth embodiment, the present disclosure provides the photovoltaic module of any one of the first to twenty-ninth embodiments, further comprising a scratch-resistant coating on at least one surface of the multilayer optical film.

In a thirtieth embodiment, the present disclosure provides the photovoltaic module of any one of the first to twenty-ninth embodiments, wherein the multilayer optical film transmits at least a portion of infrared light outside the absorption bandwidth of the photovoltaic cell.

In a thirty-first embodiment, the present disclosure provides the photovoltaic module of any one of the first to thirtieth embodiments, further comprising a celestial tracking mechanism.

In a first embodiment, the present disclosure provides photovoltaic module comprising:

a backsheet;

a plurality of photovoltaic cells overlying the backsheet, wherein the plurality of photovoltaic cells are spaced apart from each other such that open areas of the backsheet are not covered by the plurality of photovoltaic cells; and

reflective film positioned over the backsheet in at least some of the open areas of the backsheet, the reflective film comprising a multilayer optical film having an optical stack comprising a plurality of alternating first and second optical layers with different indices of refraction and having a left band edge in a range from 600 nanometers to 900 nanometers;

wherein photovoltaic cells have an absorption bandwidth, and wherein the multilayer optical film reflects at least a portion of light in a range of wavelengths that corresponds with the absorption bandwidth of the photovoltaic cell.

In a second embodiment, the present disclosure provides the photovoltaic module of the first embodiment, wherein the multilayer optical film is a color-shifting film having a left band edge in a range from 600 to 750 nanometers.

In a third embodiment, the present disclosure provides the photovoltaic module of the first or second embodiment, wherein the multilayer optical film has an average visible light transmission of at least 30 percent.

In a fourth embodiment, the present disclosure provides the photovoltaic module of the third embodiment, wherein the multilayer optical film has an average visible light transmission of at least 45 percent at an angle normal to the multilayer optical film.

In a fifth embodiment, the present disclosure provides the photovoltaic module of the third embodiment, wherein the multilayer optical film has an average visible light transmission of at least 45 percent in a wavelength range selected from the group consisting of 400 nanometers to 500 nanometers, 400 nanometers to 600 nanometers, and 400 nanometers to 700 nanometers.

In a sixth embodiment, the present disclosure provides the photovoltaic module of any one of the first to fifth embodiments, wherein the multilayer optical film has an average light reflection of at least 50 percent at a normal angle to the multilayer optical film in a wavelength range selected from the group consisting of 650 nanometers to 1100 nanometers, 650 nanometers to 1500 nanometers, 875 nanometers to 1100 nanometers, and 875 nanometers to 1500 nanometers.

In a seventh embodiment, the present disclosure provides the photovoltaic module of any one of the first to sixth embodiments, wherein the multilayer optical film has an average light transmission of at least 50 percent for wavelengths above 1200 nanometers at a normal angle to the multilayer optical film.

In an eighth embodiment, the present disclosure provides the photovoltaic module of any one of the first to seventh embodiments, wherein the reflective film is a specular reflector.

In a ninth embodiment, the present disclosure provides the photovoltaic module of any one of the first to seventh embodiments, wherein the reflective film is a diffuse reflector.

In a tenth embodiment, the present disclosure provides the photovoltaic module of any one of the first to ninth embodiments, wherein the photovoltaic cell is a crystalline silicon single junction cell, a ribbon silicon cell, a copper indium gallium selenide cell, or a gallium arsenide cell.

In an eleventh embodiment, the present disclosure provides the photovoltaic module of any one of the first to tenth embodiments, wherein the first optical layers comprise polyethylene terephthalate.

In a twelfth embodiment, the present disclosure provides the photovoltaic module of any one of the first to eleventh embodiments, wherein the second optical layers comprise poly(methyl methacrylate), copolymers of methyl methacrylate and other acrylate monomers, or blends of poly(methyl methacrylate) and poly(vinylidene difluoride).

In a thirteenth embodiment, the present disclosure provides the photovoltaic module of any one of the first to twelfth embodiments, further comprising an ultraviolet light protective layer on at least one surface of the multilayer optical film.

In a fourteenth embodiment, the present disclosure provides the photovoltaic module of the thirteenth embodiment, wherein the ultraviolet light protective layer comprises poly(vinylidene difluoride), poly(methyl methacrylate), and an ultraviolet light absorber.

In a fifteenth embodiment, the present disclosure provides the photovoltaic module of the thirteenth or fourteenth embodiment, wherein the ultraviolet light protective layer is a multilayer ultraviolet light reflective mirror.

In a sixteenth embodiment, the present disclosure provides the photovoltaic module of any one of the first to fifteenth embodiments, wherein the reflective backsheet comprises a visible light-transmitting substrate.

In a seventeenth embodiment, the present disclosure provides the photovoltaic module of the sixteenth embodiment, wherein the photovoltaic module is installed as part of a building and allows visible light to enter the building through the reflective backsheet.

In an eighteenth embodiment, the present disclosure provides the photovoltaic module of the sixteenth or seventeenth embodiment, wherein the module forms at least a portion of is a window, a skylight, or a door.

In a nineteenth embodiment, the present disclosure provides the photovoltaic module of the sixteenth or seventeenth embodiment, wherein the photovoltaic module forms at least a portion of a roof. The roof may be, for example, on a building, parking lot, or carport.

In a twentieth embodiment, the present disclosure provides the photovoltaic module of the sixteenth or seventeenth embodiment, wherein the photovoltaic module is installed in an awning.

In a twenty-first embodiment, the present disclosure provides the photovoltaic module of the sixteenth or seventeenth embodiment, wherein the photovoltaic module is installed in an atrium.

In a twenty-second embodiment, the present disclosure provides the photovoltaic module of any one of the first to fifteenth embodiments, the backsheet comprises an opaque substrate.

In a twenty-third embodiment, the present disclosure provides the photovoltaic module of the twenty-second embodiment, wherein the opaque substrate is black.

In a twenty-fourth embodiment, the present disclosure provides the photovoltaic module of the twenty-second embodiment, wherein the opaque substrate is white.

In a twenty-fifth embodiment, the present disclosure provides the photovoltaic module of any one of the first to twenty-fourth embodiments, wherein the backsheet is planar.

In a twenty-sixth embodiment, the present disclosure provides the photovoltaic module of any one of the first to twenty-fifth embodiments, wherein the multilayer optical film comprises a textured surface.

In a twenty-seventh embodiment, the present disclosure provides the photovoltaic module of the twenty-sixth embodiment, wherein the photovoltaic module further comprises an encapsulant, and wherein the multilayer optical film has a textured layer on its surface with a refractive index that is at least 0.05 different than the encapsulant.

In a twenty-eighth embodiment, the present disclosure provides the photovoltaic module of any one of the first to twenty-seventh embodiments, further comprising an anti-soiling coating on at least one surface of the multilayer optical film.

In a twenty-ninth embodiment, the present disclosure provides the photovoltaic module of any one of the first to twenty-ninth embodiments, further comprising a scratch-resistant coating on at least one surface of the multilayer optical film.

In a thirtieth embodiment, the present disclosure provides the photovoltaic module of any one of the first to twenty-ninth embodiments, wherein the multilayer optical film transmits at least a portion of infrared light outside the absorption bandwidth of the photovoltaic cell.

In a thirty-first embodiment, the present disclosure provides the photovoltaic module of any one of the first to thirtieth embodiments, further comprising a celestial tracking mechanism.

### EXAMPLES

These examples are merely for illustrative purposes only and are not meant to be limiting on the scope of the appended claims. All parts, percentages, ratios, etc. in the examples and the rest of the specification are by weight, unless noted otherwise. Solvents and other reagents used were obtained from Sigma-Aldrich Chemical Company; Milwaukee, Wisconsin unless otherwise noted.

### Film Preparations

### Film Preparation 1

A multilayer optical film was made with birefringent layers created from polyethylene terephthalate (PET) (Eastman Chemicals, Kingsport, Tenn.) and second polymer layers created from a poly(methyl methacrylate) copolymer (CoPMMA) made from 75% by weight methyl methacrylate and 25% by weight of ethyl acrylate (obtained from Atoglas Resin Division, Philadelphia, Pa., under the trade designation “PERSPEX CP63”). PET and CoPMMA were coextruded thru a multilayer polymer melt manifold to create a multilayer melt stream having 550 alternating birefringent layers and second polymer layers. A masterbatch of PET and ultraviolet light absorber (UVA) commercially available under the trade designation “TA07-07 MB02” from Sukano, Duncan, S.C. was compounded into the PET optical layers at 10 wt %. In addition, a pair of non-optical polymer blend layers were coextruded as protective skin layers on either side of the optical layer stack. The skin layers were a blend of 35 wt % PVDF (poly(vinylidene difluoride), commercially available from 3M Company, St. Paul, Minn. under the trade designation “3M DYNEON PVDF 6008/0001”, 45 wt % of poly(methyl methacrylate) (PMMA, commercially available under the trade designation “PERSPEX CP82” from Plaskolite, Campton, Calif.) and 20 wt % of a masterbatch PMMA and UVA commercially available under the trade designation “TA11-10 MB01” from Sukano. This multilayer coextruded melt stream was cast onto a chilled roll at 22 meters per minute creating a multilayer cast web with optical layers approximately 725 microns (29 mils) thick and a total thickness of 1400 microns. The multilayer cast web was then heated in a tenter oven at 105° C. for 10 seconds before being biaxially oriented to a draw ratio of 3.8 by 3.8. The oriented multilayer film was further heated to 225° C. for 10 seconds to increase crystallinity of the PET layers. Reflectivity of this multilayer near infrared mirror film was measured with a Lambda 950 spectrophotometer resulting in an average reflectivity of 92.5% over a bandwidth of 650 to 1350 nm at normal angles to the film. At a 45 degree angle, the reflectivity of this near infrared mirror film was measured with a Lambda 950 spectrophotometer resulting in an average reflectivity of 94.5% over a bandwidth of 550 to 1250 nm. This near infrared mirror film has a reddish appearance at normal angle and a gold appearance at 45 to 60 degrees off normal angle with a black background behind the mirror. This near infrared mirror film has a cyan appearance at normal angle and a cobalt blue appearance at 45 to 60 degrees off normal angle with a white background behind the mirror. This near infrared mirror film had a light transmission at normal angle to the film of 88% over the visible light wavelengths of 400 to 650 nm.

### Film Preparation 2

A multilayer optical film was made with birefringent layers created from the same PET and the same second polymer layers of CoPMMA as in Film Preparation 1. PET and CoPMMA were coextruded thru a multilayer polymer melt manifold to create a multilayer melt stream having 224 alternating birefringent layers and second polymer layers. In addition, a pair of non-optical PET layers were coextruded as protective skin layers on either side of the optical layer stack. This multilayer coextruded melt stream was cast onto a chilled roll at 22 meters per minute creating a multilayer cast web with a total thickness of approximately 700 microns thick and with a thickness of the optical layer stack of approximately 233 microns. The multilayer cast web was then heated in a tenter oven at 105° C. for 10 seconds before being biaxially oriented to a draw ratio of 3.8 by 3.8. The oriented multilayer film was further heated to 225° C. for 10 seconds to increase crystallinity of the PET layers. Reflectivity of this multilayer near infrared mirror film was measured with a Lambda 950 spectrophotometer resulting in an average reflectivity of 94% over a bandwidth of 875 to 1100 nm at normal angles to the film. At a 45 degree angle, the reflectivity of this near infrared mirror film was measured with a Lambda 950 spectrophotometer resulting in an average reflectivity of 96% over a bandwidth of 750 to 950nm. In transmitted light, this near infrared mirror film has a clear appearance at normal angle and a clear appearance at 45 to 60 degrees off normal angles. This near infrared mirror film has a light transmission of 88% over the visible light wavelengths of 400 to 700 nm.

### Prophetic Film Preparation 3

A multilayer reflective mirror can be made according to the method described in Film Preparation 1 except with coPMMA of the second polymer layers replaced by the PVDF/PMMA/UVA blend used in the skin layers of Film Preparation 1. The reflectivity measurements of this film would be expected to be higher than those of Film Preparation 1, and the appearance of this film would be expected to be similar to that of Film Preparation 1.

### Illustrative Example 1

Photovoltaic modules were made with four 2.5″×2.5″ mono-crystalline silicon cells spaced 2″ apart and laminated to glass on the front side with ethylenevinylacetate (EVA) encapsulant. Carbon black filled polyester film (available as “3M SCOTCHSHIELD FILM 15T BLACK” backside film from 3M Company, St. Paul, Minn.) was laminated to the back side with EVA (available as “PETROTHENE NA420” resin from Equistar, Houston, Tex.) encapsulant. Three modules were made with this same construction due to module variability.

A 3KW Custom Collimated Beam Solar Simulator available from ScienceTech of London, Ontario was used to irradiate the modules and produced an average power of 2.26 W as shown in Table 1. The ScienceTech solar simulator uses a 3000 W Osram XBO lamp and an AM1.5D filter to match the solar spectrum. Light from the solar simulator is collimated to +/−0.5 degrees with a Fresnel collimating lens. Irradiation level from the solar simulator was adjusted to 1050 W/m² as measured with a Daystar

Meter available from Daystar, Inc. (Las Cruces, N. Mex.). Power measurements were made with a handheld Digital Multimeter Model# DM-4400A available from Sperry Instruments (Menominee Falls, Wis.).

### Example 2

Photovoltaic modules were made identically to Illustrative Example 1 with the exception that Film Preparation 1 was placed under the photovoltaic cells between EVA encapsulant and the carbon black filled polyester film. As in Illustrative Example 1, three modules were made with this same construction due to module variability. The modules were irradiated and measured as in Illustrative Example 1 to produce an average power of 2.48 W as shown in Table 1.

TABLE 1

| Example | Voc¹ | Isc² | Watts | Avg |
|---|---|---|---|---|
| Ill. Ex 1-1 | 2.21 | 1.01 | 2.23 | |
| Ill. Ex 1-2 | 2.22 | 1.02 | 2.26 | |
| Ill. Ex 1-3 | 2.19 | 1.04 | 2.28 | 2.26 |
| Ex 2-1 | 2.26 | 1.11 | 2.51 | |
| Ex 2-2 | 2.25 | 1.1 | 2.48 | |
| Ex 2-3 | 2.26 | 1.09 | 2.46 | 2.48 |

¹Voc = open circuit voltage;
²Isc = short circuit current

### Example 3

One photovoltaic module was made as described in Example 2 with the exception that high refractive index linear prisms having 120 degree apex angles were cast and cured with 254 nm ultra-violet light onto the color mirror film before lamination. The high refractive index linear prisms were made with a resin described in Example 2 of U.S. Pat. Appl. Pub. No. 2011/227008 (Jones et al.), incorporated herein by reference, with the modification that the components in the resin were 53% zirconia nanoparticle, 11.5% of the second compound (see Example 1 and Reaction Scheme of U.S. Pat. Appl. Pub. No. 2011/227008), 3.5% of the compound comprising C₃-C₈ ester repeat unit, 9.8% phenoxyethyl acrylate, 16.4% 2-phenyl-phenyl acrylate, 6.5% “SR 601” resin obtained from Sartomer, Exton, Pa., 0.6% “DAROCURE 1173” photoinitiator from BASF, Florham Park, NJ, and 0.75% “LUCIRIN TPO” photoinitiator from BASF. The uncured resin had a refractive index of 1.625. The refractive index difference between the high refractive index prisms and EVA encapsulant refracted the reflected light at an angle of incidence such that it would have total internal reflection from the glass/air interface back onto the photovoltaic cell. The photovoltaic module therefore produced more power than without high refractive index prisms. The module was irradiated and measured as in Illustrative Example 1. A comparison between the results obtained for Example 3 and for a repeat of one module of Illustrative Example 1 is shown in Table 2, below.

TABLE 2

| Example | Voc¹ | Isc² | Avg. Watts |
|---|---|---|---|
| Ill. Ex. 1 | 2.22 | 1.02 | 2.26 |
| Ex. 3 | 2.36 | 1.25 | 2.95 |
| Ill. Ex. 4 | 2.33 | 1.22 | 2.84 |

¹Voc = open circuit voltage;
²Isc = short circuit current

### Illustrative Example 4

One photovoltaic module was made identically to Illustrative Example 1 with the exception that a white backsheet obtained from 3M Company under the trade designation “3M SCOTCHSHIELD FILM 17” white backside film was used instead of the carbon black filled polyester film. The module was irradiated and measured as in Illustrative Example 1 to produce an average power of 2.84 W as shown in Table 2, above.

### Prophetic Example

Photovoltaic modules could be made similar to Example 2 with the exception that high refractive index linear prisms having 120 degree apex angles made from the CoPEN polymer preparation described below would be extrusion coated onto the color mirror film before lamination. The refractive index difference between the high refractive index prisms and EVA encapsulant would refract the reflected light at an angle of incidence such that it would have total internal reflection from the glass/air interface back onto the photovoltaic cell. The photovoltaic module made as described with a back sheet having high refractive index prisms on color mirror film would produce more power than without high refractive index prisms.

### CoPEN Polymer Preparation Example

Copolyethylenenaphthalate used to form the high refractive index prisms was synthesized in a batch reactor with the following raw material charge; 114.8 killograms (kg) dimethyl naphthalene dicarboxylate. 30.4 kg dimethyl terephthalate, 75 kg ethylene glycol, 5.9 kg hexane diol, 29 grams (g) cobalt acetate, 29 g zinc acetate, 200 g trimethylol propane, and 51 g antimony tri-acetate. Under pressure of 2 atm (0.2 megapascals), this mixture was heated to 254° C. while removing the transesterification reaction by-product methanol. After 39.6 kg of methanol was removed, 56 g of triethyl phosphonoacetate was charged to the reactor and then the pressure was gradually reduced to 1 torr (133 Pa) while heating to 290° C. The condensation reaction by-product, ethylene glycol, was continuously stripped until a polymer with an Intrinsic Viscosity of 0.52, as measured in 60/40 Phenol/dichlorobenzene, was produced. Refractive index of the the CoPEN was measured to 1.626 with a Metricon refractometer.

Various modifications and alterations of this disclosure may be made by those skilled in the art without departing from the scope and spirit of this disclosure, and it should be understood that this disclosure is not to be unduly limited to the illustrative embodiments set forth herein.

1. A photovoltaic module comprising:
a reflective backsheet comprising a multilayer optical film having an optical stack comprising a plurality of alternating first and second optical layers with different indices of refraction and having a left band edge in a range from 600 nanometers to 900 nanometers; and
a plurality of photovoltaic cells overlying the reflective backsheet, wherein the plurality of photovoltaic cells are spaced apart from each other such that open areas of the reflective backsheet are not covered by the plurality of photovoltaic cells;
wherein photovoltaic cells have an absorption bandwidth, and wherein the multilayer optical film reflects at least a portion of light in a range of wavelengths that corresponds with the absorption bandwidth of the photovoltaic cell.

2. A photovoltaic module comprising:
a backsheet;
a plurality of photovoltaic cells overlying the backsheet, wherein the plurality of photovoltaic cells are spaced apart from each other such that open areas of the backsheet are not covered by the plurality of photovoltaic cells; and
reflective film positioned over the backsheet in at least some of the open areas of the backsheet, the reflective film comprising a multilayer optical film having an optical stack comprising a plurality of alternating first and second optical layers with different indices of refraction and having a left band edge in a range from 600 nanometers to 900 nanometers;
wherein photovoltaic cells have an absorption bandwidth, and wherein the multilayer optical film reflects at least a portion of light in a range of wavelengths that corresponds with the absorption bandwidth of the photovoltaic cell.

3. The photovoltaic module of claim 1, wherein the multilayer optical film is a color-shifting film having a left band edge in a range from 600 to 750 nanometers.

4. The photovoltaic module of claim 1, wherein the multilayer optical film has an average visible light transmission of at least 30 percent.

5. The photovoltaic module of claim 1, wherein the multilayer optical film has an average light reflection of at least 50 percent at a normal angle to the multilayer optical film in a wavelength range selected from the group consisting of 650 nanometers to 1100 nanometers, 650 nanometers to 1500 nanometers, 875 nanometers to 1100 nanometers, and 875 nanometers to 1500 nanometers.

6. The photovoltaic module of claim 1, wherein the multilayer optical film has an average light transmission of at least 50 percent for wavelengths above 1200 nanometers at a normal angle to the multilayer optical film.

7. The photovoltaic module of claim 1, further comprising an ultraviolet light protective layer on at least one surface of the multilayer optical film.

8. The photovoltaic module of claim 1, wherein the reflective backsheet or the reflective film is a specular reflector.

9. The photovoltaic module of claim 1, wherein the reflective backsheet or the reflective film is a diffuse reflector.

10. The photovoltaic module of claim 1, wherein the backsheet is planar.

11. The photovoltaic module of claim 1, wherein the backsheet comprises a visible light-transmitting substrate.

12. The photovoltaic module of claim 1, wherein the photovoltaic module is installed in a building and allows visible light to enter the building through the backsheet.

13. The photovoltaic module of claim 1, wherein the backsheet comprises an opaque substrate.

14. The photovoltaic module of claim 1, wherein the multilayer optical film comprises a textured surface.

15. The photovoltaic module of claim 1, wherein the photovoltaic cell is a crystalline silicon single junction cell, a ribbon silicon cell, a copper indium gallium selenide cell, or a gallium arsenide cell.

16. The photovoltaic module of claim 2, wherein the multilayer optical film is a color-shifting film having a left band edge in a range from 600 to 750 nanometers.

17. The photovoltaic module of claim 2, wherein the multilayer optical film has an average visible light transmission of at least 30 percent.

18. The photovoltaic module of claim 2, wherein the multilayer optical film has an average light reflection of at least 50 percent at a normal angle to the multilayer optical film in a wavelength range selected from the group consisting of 650 nanometers to 1100 nanometers, 650 nanometers to 1500 nanometers, 875 nanometers to 1100 nanometers, and 875 nanometers to 1500 nanometers.

19. The photovoltaic module of claim 2, wherein the multilayer optical film has an average light transmission of at least 50 percent for wavelengths above 1200 nanometers at a normal angle to the multilayer optical film.

20. The photovoltaic module of claim 2, wherein the backsheet comprises a visible light-transmitting substrate.
